(19) United States
(12) Patent Application Publication
(10) Pub. No.: US 2001/0052648 A1
(43) Pub. Date: Dec. 20, 2001

(54) SEMICONDUCTOR DEVICE AND METHOD OF MANUFACTURING THE SAME

(76) Inventors: TOMOHIRO SAKURAI, HYOGO (JP); ATSUSHI MAEDA, HYOGO (JP); KENJI YOSHIYAMA, HYOGO (JP)

Correspondence Address: MCDERMOTT WILL & EMERY, 600 13TH STREET, N.W., WASHINGTON, DC, 20005-3096, US

(21) Appl. No.: 09/352,348

(22) Filed: Jul. 13, 1999

(30) Foreign Application Priority Data
Feb. 2, 1999 (JP) 11-024889(P)

(51) Int. Cl. H01L 21/3205; H01L 21/4763; H01L 23/48; H01L 23/52; H01L 29/40

(52) U.S. Cl. 257/754

(57) ABSTRACT

A silicide layer in direct contact with a gate electrode layer of a MOS transistor is formed only in a contact hole reaching the gate electrode layer, and is located only in the bottom portion of the contact hole. Thereby, increase in gate interconnection resistance is prevented, and thereby decrease in drive power of the transistor can be prevented.

### BACKGROUND OF THE INVENTION

1. Field of the Invention

The present invention relates to a semiconductor device and a method of manufacturing the same, and particularly a semiconductor device having a silicide layer as well as a method of manufacturing the same.

2. Description of the Background Art

First, a semiconductor device in the prior art will now be described below. In the following description, CoSi₂ is discussed as an example of silicide.

FIG. 29 is a cross section schematically showing a structure of a conventional semiconductor device. Referring to FIG. 29, a well region 302 is formed at a surface of a silicon substrate 301 isolated by an isolating oxide film 303. An MOS (Metal Oxide Semiconductor) transistor 310 is formed on the surface of well region 302.

MOS transistor 310 is provided with a pair of source/drain regions 304, a gate oxide film 305 and a gate electrode layer (306 and 307a). Each of source/drain regions 304 has an LDD (Lightly Doped Drain) structure having a lightly doped diffusion region 304a and a heavily doped diffusion region 304b, and includes a CoSi₂ layer 307b in contact with heavily doped diffusion region 304b. Gate electrode layer (306 and 307a) is formed on a region located between paired source/drain regions 304 with gate oxide film 305 therebetween. Gate electrode layer (306 and 307a) has a doped polycrystalline silicon layer 306, i.e., polycrystalline silicon layer doped with impurity and a CoSi₂ layer 307aformed on the doped polycrystalline silicon layer 306.

Side walls of gate electrode layer (306 and 307a) are covered with a side wall insulating layer 309.

An insulating layer 311 is formed over MOS transistor 310. Insulating layer 311 is provided with a contact hole 311a reaching gate electrode layer (306 and 307a), and contact holes 311b reaching source/drain regions 304, respectively. -Contact holes 311a and 311b are filled with plug layers 313 made of W (tungsten) with barrier metal layers 312 made of TiN (titanium nitride) therebetween. Interconnection layers 314 made of Al (aluminum) allay are formed on insulating layer 311 and are in contact with barrier metal layer 312 and plug layers 313.

A method of manufacturing the conventional semiconductor device will now be described.

FIGS. 30 to 34 are schematic cross sections showing, in the order of steps, a method of manufacturing the conventional semiconductor device. Referring first to FIG. 30, isolating oxide film 303 is formed on the surface of silicon substrate 301, and thereby well region 302 is formed. Thereafter, gate oxide film 305 is formed, and doped polycrystalline silicon layer 306 which will form the gate electrode is deposited. Then, patterning is effected by ordinary photolithography and etching techniques.

Doped polycrystalline silicon layer 306 thus patterned and others are used as a mask, and ion implantation is effected to form lightly doped diffusion regions 304a. After forming side wall insulating layer 307 on the side walls of doped polycrystalline silicon layer 306, ion implantation is performed with a mask formed of gate electrode layer 306, side wall insulating layer 307 and others to form heavily doped diffusion regions 304b. Thereafter, Co (cobalt) layer 307 is formed on the entire surface by sputtering. First annealing is effected at a relatively low temperature for a short time.

Referring to FIG. 31, the above annealing causes reaction between Si (silicon) and Co at the surfaces of heavily doped diffusion regions 304b and doped polycrystalline silicon layer 306 so that CoSi layers 307aand 307b are formed.

The above reaction does not occur on the side wall insulating layer 309 and isolating oxide film 303, and therefore the CoSi layer is not formed thereon. Thereafter, unreacted Co layer 307 is removed with mixed acid Phosphoric acid+nitric acid+acetic acid+pure water) and hydrogen peroxide solution, or the like.

Referring to FIG. 32, second annealing is effected at a relatively high temperature for a short time. This changes the composition of CoSi layers 307aand 307b on doped polycrystalline silicon layer 306 and heavily doped diffusion regions 304b into CoSi₂.

Referring to FIG. 33, insulating layer 311 is deposited over the entire surface, and flattening is effected thereon.

Referring to FIG. 34, etching with plasma or the like is performed to form contact holes 311a and 311b in insulating layer 311. Contact hole 311a thus formed reaches gate electrode layer (306 and 307a), and contact holes 311b reach source/drain regions 304, respectively.

The conventional semiconductor device suffers from the two problems, which will now be described.

(1) In the structure having insulating layer 311 which has the flattened top surface as shown in FIG. 33, a distance from the top surface of insulating layer 311 to gate electrode layer (306 and 307a) is smaller than a distance from the top surface of insulating layer 311 to source/drain regions 304. Therefore, if the processing is performed to form contact hole 311a simultaneously with contact hole 311b, contact hole 311a first reach gate electrode layer (306 and 307a). Thereafter, the top surface of gate electrode layer (306 and 307a) exposed in contact hole 311a is further etched until contact holes 311b reach the top surfaces of source/drain regions 304, respectively. Accordingly, the top surface of silicide layer 307ais shave off, and the interconnection resistance of the gate locally rises. This lowers the drive performance of MOS transistor 310.

(2) In the prior art, CoSi₂ layers 307b are formed entirely over the exposed surfaces of heavily doped diffusion regions 304b. In an edge region P1 of isolating oxide film 303 and a gate edge region P2, therefore, CoSi₂ layer 307 is spaced from a pn junction surface between well region 302 and heavily doped diffusion region 304b by shorter distances L1 and L2 than the other portions, respectively, so that junction leak is likely to occur. CoSi₂ layer 307b is formed on the whole exposed surface of diffusion region 304b, and occupies a large planar area. This increases a possibility of the junction leak. When the junction leak occurs, an off-leak current of MOS transistor 310 increases, resulting in disadvantageously increase in power consumption.

### SUMMARY OF THE INVENTION

An object of the invention is to prevent increase in gate interconnection resistance and thereby prevent decrease in drive performance of a transistor.

Another object of the invention is to suppress an off-leak current of a transistor, and thereby decrease a power consumption.

According to the invention, a semiconductor device includes a conductive layer patterned and including a silicon layer, an insulating layer covering the conductive layer and having a first hole reaching the conductive layer, a first silicide layer formed only within the first hole, located only in a bottom portion of the first hole and being in contact with the conductive layer, and a first interconnection layer electrically connected to the first silicide layer through the first hole.

According to the semiconductor device of the invention, the first silicide layer which is in contact with the conductive layer such as a gate is formed on the bottom surface of the first hole extended to the conductive layer such as a gate. Therefore, the first silicide layer can compensate the conductive layer for shaving of the top surface thereof caused by overetching during formation of the first hole. Accordingly, increase in interconnection resistance of the conductive layer such as a gate can be prevented, and disadvantages such as reduction in drive performance of the transistor can be prevented.

Also, the first silicide layer can reduce the contact resistance between the conductive layer and the first interconnection layer.

Preferably, the semiconductor device further includes a semiconductor substrate having a main surface, and a conductive region including an impurity region formed at the main surface of the semiconductor substrate. The insulating layer has a second hole reaching the conductive region. The semiconductor device further includes a second silicide layer formed only in the second hole, located only in the bottom portion of the second hole and being in contact with the conductive region, and a second interconnection layer electrically connected to the second silicide layer through the second hole.

According to the above structure, the second silicide layer can be formed not on the entire surface of the impurity region but on only a portion of the same. Therefore, a large distance can be ensured between the second silicide layer and a pn junction surface between the substrate region and the impurity region so that occurrence of junction leak can be suppressed. The planar area occupied by the second silicide layer can be smaller than that in the prior art. This can also suppress occurrence of the junction leak. Since the occurrence of the junction leak can be suppressed as described above, an off-leak current of the transistor or the like can be suppressed, and the power consumption can be reduced.

Further, the second silicide layer can reduce the contact resistance between the impurity region and the second interconnection layer.

Preferably, in the above semiconductor device, the conductive layer has a third silicide layer in contact with the top surface of the silicon layer, and the silicide layer for the silicon layer formed of the first and third silicide layers has a first portion located outside the first hole and a second portion located in the first hole and having a larger thickness than the first portion.

Accordingly, the thickness of the silicide in the hole is not thin in contrast to the prior art so that increase in interconnection resistance can be prevented, and disadvantages such as reduction in drive performance of the transistor can be prevented.

Preferably, in the above semiconductor device, the conductive region has a fourth silicide layer in contact with the top surface of the impurity region, and the silicide layer for the impurity region formed of the second and fourth silicide layers has a third portion located outside the second hole and a fourth portion located in the second hole and having a larger thickness than the third portion.

Accordingly, the thickness of the silicide in the hole is not reduced in contrast to the prior art.

Preferably, the semiconductor device further includes first and second insulated gate type field-effect transistors. The first insulated gate type field-effect transistor has a gate electrode layer formed of the silicon layer and source/drain region formed of the impurity region. The second insulated gate type field-effect transistor has a gate electrode layer formed of the silicon layer and the third silicide layer, and source/drain region formed of the impurity region and the fourth silicide layer.

Thereby, two kinds of transistors can be arranged in a mixed fashion in the single chip.

A method of manufacturing a semiconductor device according to the invention includes the steps of forming a conductive layer including a silicon layer by patterning; forming an insulating layer covering the conductive layer and having a first hole reaching the conductive layer; forming a first metal layer on the insulating layer and in the first hole; forming only in the first hole a first silicide layer located only in the bottom portion of the first hole and being in contact with the conductive layer by changing a contact portion between the first metal layer and the conductive layer into silicide; and forming a first interconnection layer electrically connected to the first silicide layer through the first hole.

According to the manufacturing method of the semiconductor device of the invention, the first silicide layer can be formed in a self-aligning manner by utilizing the pattern of the first hole. Therefore, especial steps such as a photolithography step are not required for forming the first silicide layer, and the manufacturing steps can be simplified.

Preferably, the above method of manufacturing the semiconductor device further includes the steps of forming a conductive region including an impurity region at a main surface of a semiconductor substrate; forming in the insulating layer a second hole reaching the conductive region; forming only in the second hole a second silicide layer located only in the bottom portion of the second hole and being in contact with the conductive region by changing the metal layer formed in the second hole into silicide; and forming a second interconnection layer electrically connected to the second silicide layer through the second hole.

According to the above method, the second silicide layer can be formed in a self-aligning manner by utilizing the pattern of the second hole. Therefore, especial steps such as a photolithography step are not required for forming the second silicide layer, and the manufacturing steps can be simplified.

Preferably, in the above method of manufacturing the semiconductor device, the conductive layer formed by the above step has a third silicide layer in contact with the top surface of the silicon layer, and the silicide layer for the silicon layer is formed of the first and third silicide layers and has a first portion located outside the first hole and a second portion located in the first hole and having a larger thickness that the first portion.

Accordingly, the thickness of the silicide in the hole is not reduced in contrast to the prior art so that increase in interconnection resistance due to the reduced thickness can be prevented, and disadvantages such as reduction in drive performance of the transistor can be prevented.

Preferably, in the above method of manufacturing the semiconductor device, the conductive region formed by the above step has a fourth silicide layer in contact with the top surface of the impurity region, and the silicide layer for the impurity region formed of the second and fourth silicide layers and has a third portion located outside the second hole and a fourth portion located in the second hole and having a larger thickness than the third portion.

Accordingly, the thickness of the silicide in the hole is not reduced in contrast to the prior art.

Preferably, in the method of manufacturing the semiconductor device described above, the step of forming the third and fourth silicide layers further includes the steps of forming a second metal layer in contact with the top surfaces of the impurity region and the silicon layer; and forming a third silicide layer located on the top surface of the silicon layer and a fourth silicide layer located on the top surface of the impurity region by changing a contact portion between the second metal layer and the impurity region and a contact portion between the second metal layer and the silicon layer into silicide, respectively.

According to the above method, the third and fourth silicide layers can be formed in a self-aligning manner. Therefore, especial steps such as a photolithography step are not required for forming the third and fourth silicide layers, and the manufacturing steps can be simplified.

Preferably, in the above method of manufacturing the semiconductor device, first and second insulated gate type field-effect transistors are formed. The first insulated gate field-effect transistor has a gate electrode layer formed of the silicon layer and source/drain region formed of the impurity region. The second insulated gate type field-effect transistor has a gate electrode layer formed of the silicon layer and the third silicide layer, and source/drain region formed of the impurity region and the fourth silicide layer.

Thereby, two kinds of transistors can be arranged in the single chip.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 schematically shows a structure of a semiconductor device of an embodiment 1 of the invention;

FIGS. 2 to 11 are schematic cross sections showing, in the order of steps, a method of manufacturing the semiconductor device of the embodiment 1 of the invention, respectively;

FIG. 12 schematically shows a structure of a semiconductor device of an embodiment 2 of the invention;

FIGS. 13 to 15 are schematic cross sections showing, in the order of steps, a method of manufacturing the semiconductor device of the embodiment 2 of the invention, respectively;

FIG. 16 schematically shows a structure of a semiconductor device of an embodiment 3 of the invention;

FIGS. 17 to 23 are schematic cross sections showing, in the order of steps, a method of manufacturing the semiconductor device of the embodiment 3 of the invention, respectively;

FIG. 24 schematically shows a structure of a semiconductor device of an embodiment 4 of the invention;

FIGS. 25 to 28 are schematic cross sections showing, in the order of steps, a method of manufacturing the semiconductor device of the embodiment 4 of the invention, respectively;

FIG. 29 is a cross section schematically showing a structure of a conventional semiconductor device; and

FIGS. 30 to 34 are schematic cross sections showing, in the order of steps, a method of manufacturing the semiconductor device in the prior art, respectively.

### DESCRIPTION OF THE PREFERRED EMBODIMENTS

Embodiments of the invention will now be described.

Embodiment 1

An embodiment 1 which will now be described employs CoSi₂ and an nMOS transistor.

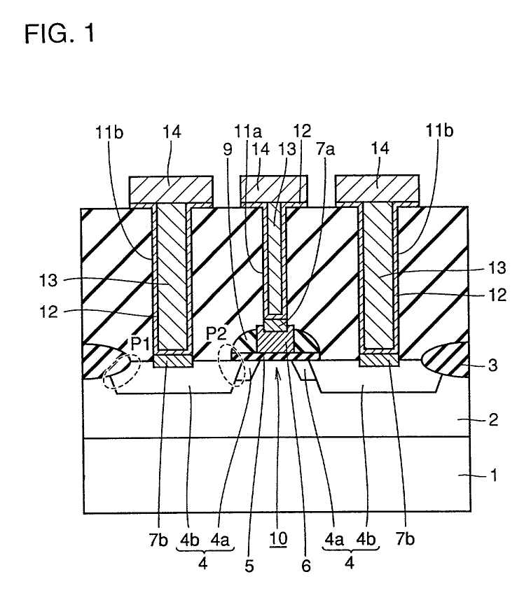

Referring to FIG. 1, a p-type well region 2 is formed at a surface of a silicon substrate 1. A surface of well region 2 is electrically isolated by isolating oxide film 3. An nMOS transistor 10 is formed on the surface of well region 2.

nMOS transistor 10 has a pair of n-type source/drain regions 4, a gate oxide film 5 and a gate electrode layer 6. Each of source/drain regions 4 has an LDD structure formed of a lightly doped diffusion region 4a and a heavily doped diffusion region 4b. Gate electrode layer 6 is formed of, e.g., a doped polycrystalline silicon layer, and is located on a region between paired source/drain regions 4 with gate oxide film 5 therebetween.

A side wall insulating layer 9 is formed over the side wall or surface of gate electrode layer 6.

NMOS transistor 10 is covered with an insulating layer 11, which is made of, e.g., USG (Undoped Silicate Glass) or BPSG (Boro Phospho Silicate Glass) and is formed on the entire surface the above structure. Insulating layer 11 is provided with a contact hole 11a reaching the surface of gate electrode layer 6 and contact holes 11b reaching the paired source/drain regions 4, respectively. Silicide layers 7a and 7b made of, e.g., CoSi₂ are formed in contact hole 11a and each contact hole 11b and particularly in bottom portions of holes 11a and 11b, and are in direct contact with gate electrode layer 6 and heavily doped diffusion region 4b, respectively.

In the specification, contact holes 11a and 11b are basically considered as holes formed in insulating layer 11, but contact holes 11a and 11b also contain the portions in gate electrode layer 6 or source/drain regions 4 which are shaved or removed by the overetching.

Contact holes 11a and 11b are filled with plug layers 13 made of W (tungsten) with barrier metal layers 12 made of TiN (titanium nitride) therebetween, respectively. Patterned interconnection layers 14 made of, e.g., Al (aluminum) alloy is formed on insulating layer 11 and is in contact with barrier metal layers 12 and plug layers 13.

A manufacturing method of the embodiment will now be described.

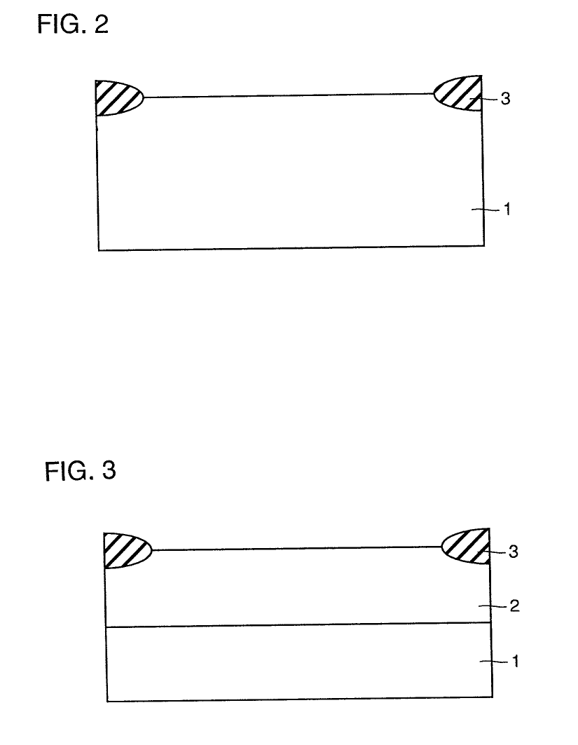

Referring first to FIG. 2, an LOCOS (Local Oxidation of Silicon) method or a trench isolation method is executed to form isolating oxide film 3 on the surface of silicon substrate 1.

Referring to FIG. 3, well region 2 is formed at the surface of silicon substrate 1. Well region 2 is formed by implanting boron into the substrate with an implantation energy from 200 to 300 keV and an implantation dose from 10¹² to 10¹³ cm⁻², if the well region 2 is of the p-type.

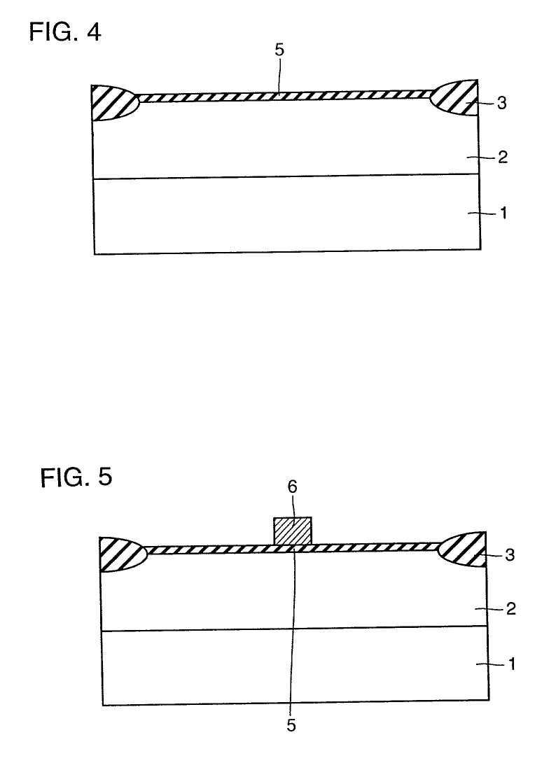

Referring to FIG. 4, thermal oxidation or the like is executed to form gate oxide film 5 of 50-60 Å in thickness on the surface of well region 2.

Referring to FIG. 5, doped polycrystalline silicon layer 6 of 200-300 nm in thickness is formed on the whole surface, and then is patterned to form gate electrode layer 6 by ordinary photolithography and etching technique.

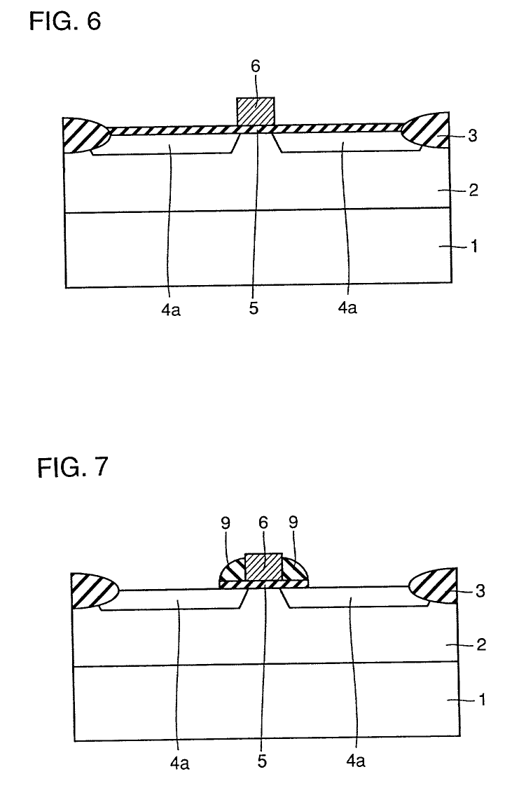

Referring to FIG. 6, impurity is implanted into the above structure masked with gate electrode layer 6 and isolating oxide film 3 so that the pair of lightly doped diffusion regions 4a are formed at the surface of well region 2. In this processing, n-type impurity is implanted under the conditions of several 10 keV and 10¹⁴ cm⁻², if lightly doped diffusion region 4a has an n-type conductivity.

Referring to FIG. 7, a film such as silicon oxide film 9 is formed on the whole surface, and anisotropic etching is effected on the whole surface of silicon oxide film 9. This leaves silicon oxide film 9 covering the side walls of gate electrode layer 6, and therefore provides side wall insulating layer 9 having a width of 80-100 nm on each side.

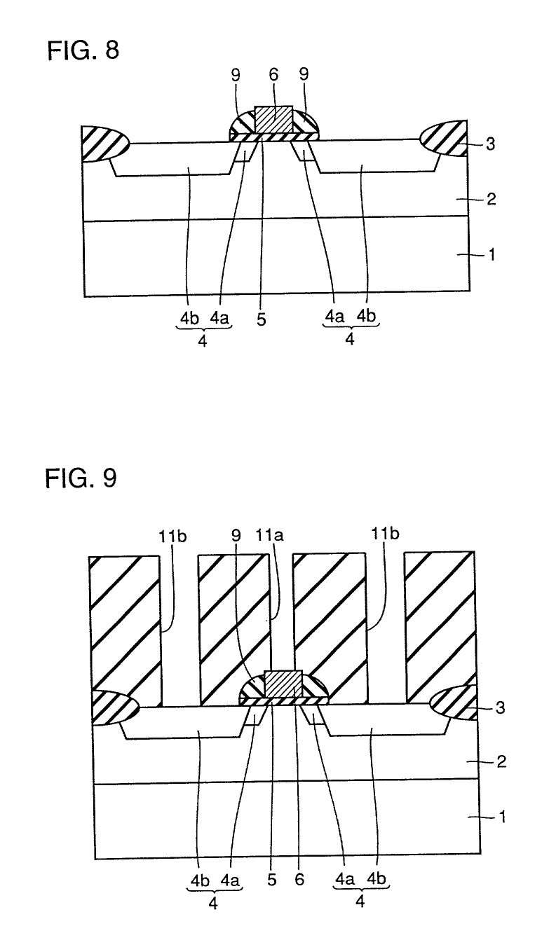

Referring to FIG. 8, impurity is implanted into the structure masked with gate electrode layer 6, side wall insulating layer 9 and isolating oxide film 3 so that the pair of heavily doped diffusion regions 4b are formed at the surface of well region 2. If the heavily doped diffusion region 4b has the n-type conductivity, the above implantation is performed by implanting n-type impurity under the conditions of several 10 keV and 10^{15 cm}⁻². Lightly doped regions 4a and heavily doped regions 4b form source/drain regions 4 of the LDD structures.

Referring to FIG. 9, insulating layer 11 made of, e.g., USG or BPSG and having a thickness of about 1000 nm is formed over the whole surface, and is flattened. Processing by ordinary photolithography and oxide film etching with plasma are effected on insulating layer 11 to form contact hole 11a reaching gate electrode layer 6 and contact holes 11b reaching source/drain regions 4.

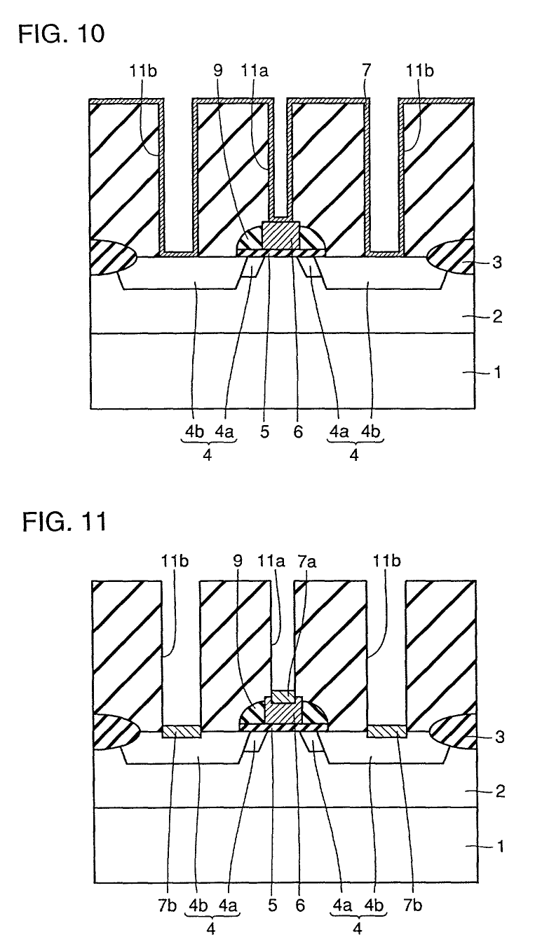

Referring to FIG. 10, sputtering is executed to deposit metal layer made 7 of, e.g., Co (Cobalt) and having a thickness of several to ten-odd nanometers on the whole surface. Thereafter, first annealing is performed.

Referring to FIG. 11, this annealing causes reaction between Si and Co in regions where metal layer 7 is in contact with gate electrode layer 6 and source/drain regions 4 so that CoSi layers 7aand 7b are formed. In the other regions, the reaction does not occur, and the CoSi layer is not formed. The unreacted portions of the metal layer 7 are removed by mixed acid. Thereafter, second annealing is performed. This changes the composition of CoSi layers 7aand 7b so that silicide layers 7aand 7b made of CoSi₂ are formed.

The first annealing is performed at a relatively low temperature for a short time, and the second annealing is performed at a relatively high temperature for a short time. Thereby, CoSi₂ layers 7a and 7b in contact with gate electrode layer 6 and source/drain regions 4 are formed only in contact holes 11a and 11b and are located only in the bottom portions thereof, respectively.

Thereafter, processing is performed to form barrier metal layers 12, plug layers 13 and interconnection layers 14, which are made of, e.g., TiN, W and Al alloy, respectively, so that the structure shown in FIG. 1 is completed.

In this embodiment, silicide layer 7a which in direct contact with gate electrode layer 6 is formed on the bottom surface of contact hole 11a reaching gate electrode layer 6 as shown in FIG. 1. Therefore, silicide layer 7a can compensate gate electrode layer 6 for shaving of its top surface which was caused during formation of contact hole 11a. Accordingly, increase in interconnection resistance of gate electrode layer 6 can be prevented, and disadvantages such as decrease in drive performance of the transistor can be prevented.

Since silicide layer 7a s formed between interconnection layer 14 and gate electrode layer 6, the contact resistance can be small.

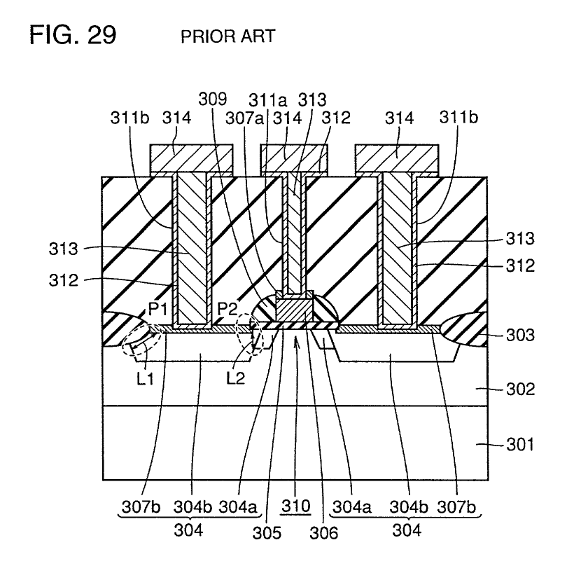

The silicide layer 7b is formed only in the bottom portion of contact hole 11b, and is not expanded over the entire surface of source/drain region 4. Therefore, silicide layer 7b does not reach edge portion P1 of isolating oxide film 303 and gate edge portion P2. Accordingly, a distance from silicide layer 7b to the pn junction interface between well region 2 and each of source/drain regions 4 can be larger than that in the prior art shown in FIG. 29, and therefore, occurrence of junction leak can be suppressed. Since a planar area occupied by silicide layer 7b can be smaller than that in the prior art shown in FIG. 29, this can likewise suppress occurrence of the junction leak. Since the junction leak can be suppressed as described above, the off-leak current of the transistor can be suppressed, and the current consumption can be reduced.

Since silicide layer 7b is formed between interconnection layer 14 and each of source/drain regions 4, the contact resistance can be small.

According to the manufacturing method of the embodiment, as shown in FIGS. 10 and 11, silicide layers 7a and 7b can be formed in the self-aligning manner because the pattern of contact holes 11a and 11b is utilized. Therefore, especial steps such as a photolithography step is not required for forming silicide layers 7a and 7b so that manufacturing steps can be simplified.

Embodiment 2

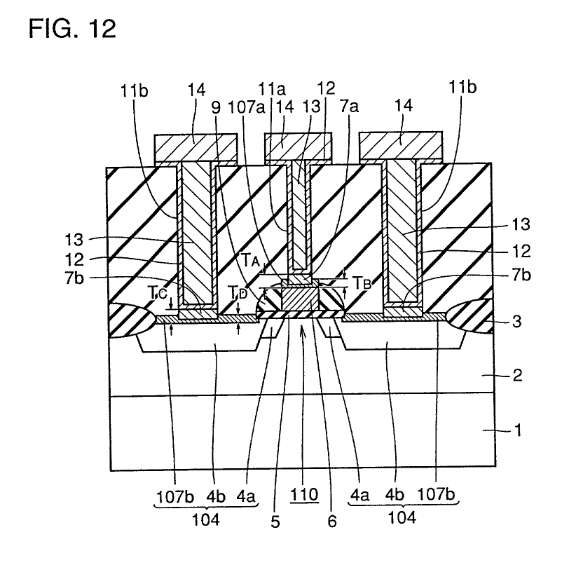

Referring to FIG. 12, this embodiment differs from the embodiment 1 in that the embodiment 2 additionally includes silicide layers 107a and 107b. Silicide layer 107a is formed in contact with the top surface of doped polycrystalline silicon layer 6, and forms the gate electrode layer together with doped polycrystalline silicon layer 6. The bottom surface of silicide layer 7a may be in direct contact with silicide layer 107a or doped polycrystalline silicon layer 6.

Silicide layer 107b is formed on the whole surface of heavily doped diffusion region 4b which is not covered with side wall insulating layer 9 and isolating oxide film 3, and forms source/drain regions together with lightly doped diffusion regions 4a and heavily doped diffusion regions 4b. The lower surface of silicide layer 7b may be in direct contact with silicide layer 107b or heavily doped diffusion region 4b.

Silicide layers 107a and 107b are made of, e.g., CoSi₂.

A sum of thicknesses of silicide layers 7a and 107a on doped polycrystalline silicon layer 6 depends on the position, and a total thickness T_{A} of the portions in contact hole 11a is larger than a total thickness T_{B} of the portions outside contact hole 11a. A sum of thicknesses of silicide layers 7b and 107b on heavily doped diffusion region 4b depends on the position, and a total thickness T_{c} of the portions in contact hole 11b is larger than a total thickness T_{D} of the portions outside contact hole 11b.

Thicknesses T_{A} and T_{c} in contact holes 11a and 11b means the thicknesses of the portions located immediately under contact holes 11a and 11b, respectively.

Structures other than the above are the substantially same as those of the embodiment 1, and therefore will not be described. The same parts and members bear the same reference numbers.

A manufacturing method of this embodiment will now be described.

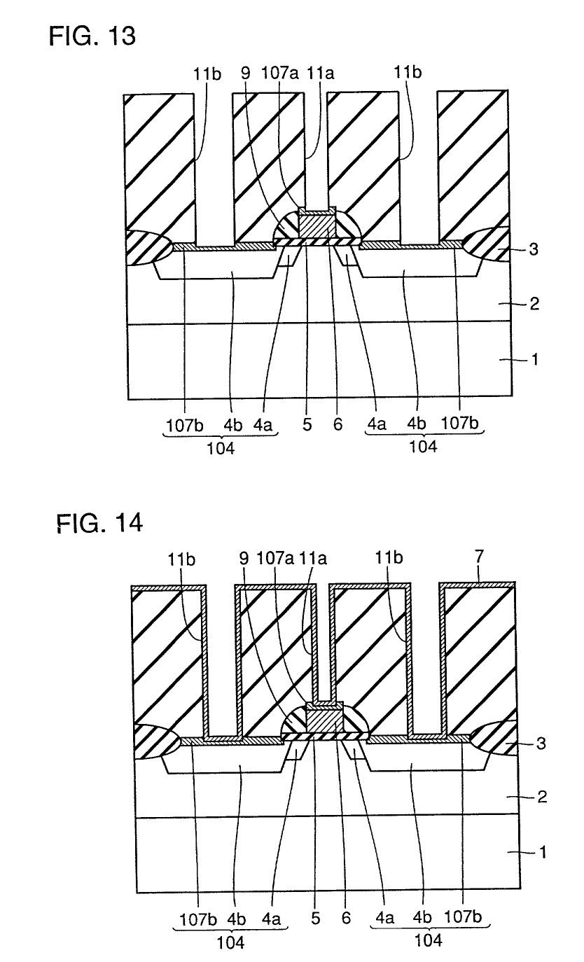

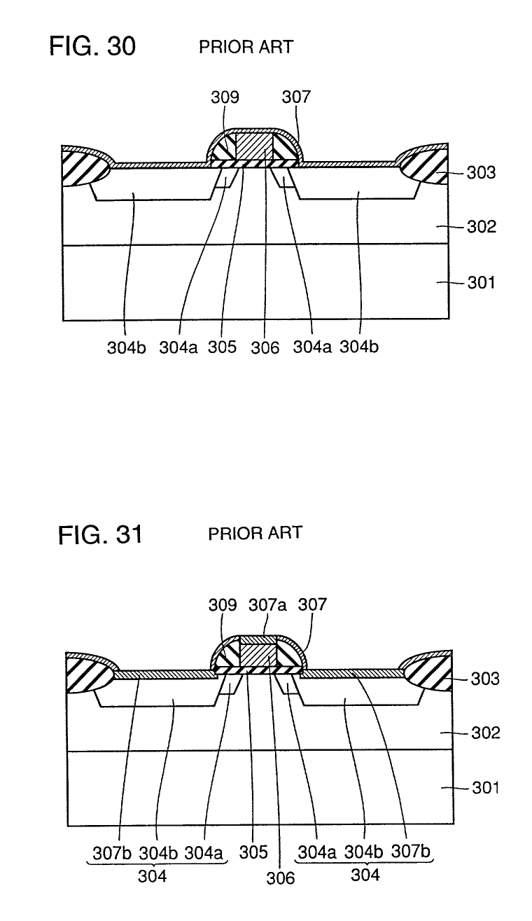

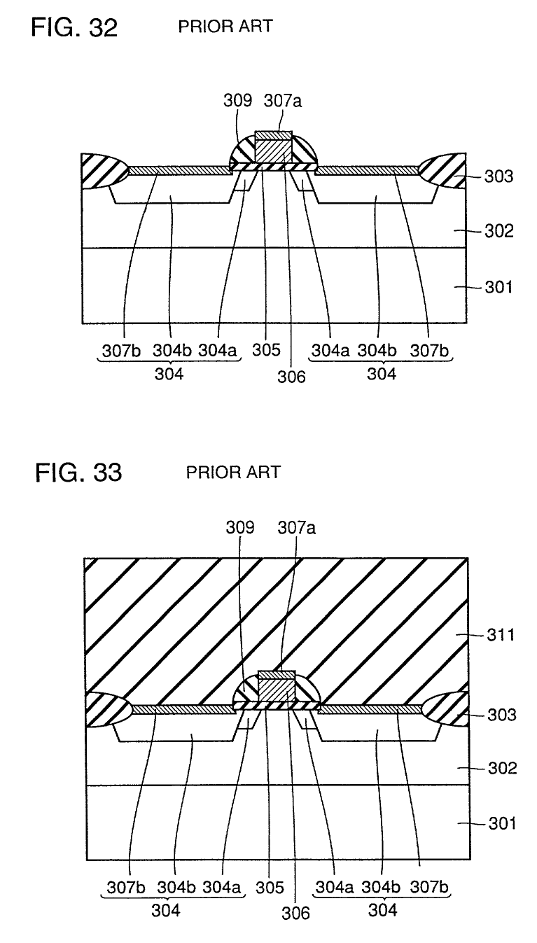

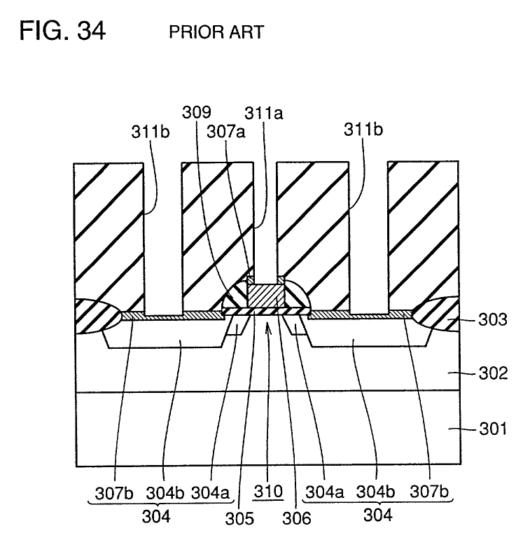

According to the manufacturing method of this embodiment, the same steps as those of the embodiment 1 shown in FIGS. 2 to 8 are performed, and then steps similar to those in the prior art shown in FIGS. 30 to 32 are performed. Thereby, silicide layer 107a is formed on doped polycrystalline silicon layer 6, and silicide layer 107b is formed on each heavily doped diffusion region 4b as shown in FIG. 13. Thereafter, insulating layer 8 made of, e.g., USG or BPSG is formed over the whole surface. The ordinary photolithography and oxide film etching with plasma are effected on insulating layer 8 to form contact hole 11a reaching gate electrode layer (6 and 107a ) as well as contact holes 11b reaching source/drain regions 104.

Referring to FIG. 14, sputtering is performed to deposit metal layer 7, which is made of, e.g., Co and has a thickness of several to ten-odd nanometers, on the entire surface. Thereafter, first annealing is effected.

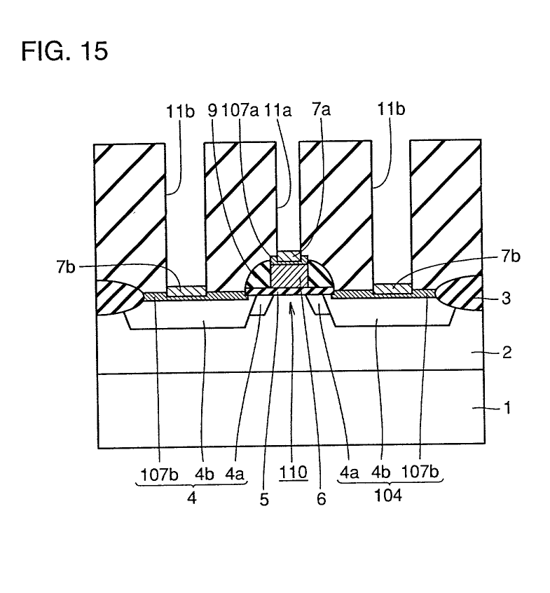

Referring to FIG. 15, this annealing causes reaction between Co and Si in the regions where metal layer 7 is in contact with gate electrode layer (6 and 107a) as well as source/drain regions 104 so that CoSi layers 7aand 7b are formed. Reaction does not occur, and therefore the CoSi layer is not formed in the other regions.

The unreacted portions of metal layer 7 are removed by mixed acid. Thereby, CoSi layers 7a and 7b are left on only the gate electrode layer and the source/drain regions. Thereafter, second annealing is effected so that the composition of CoSi layers 7a and 7b change, and silicide layers 7a and 7b made of CoSi₂ are formed.

The first annealing is performed at a relatively low temperature for a short time, and the second annealing is performed at a relatively high temperature for a short time.

Thereafter, processing is performed to form barrier metal layers 12, plug layers 13 and interconnection layers 14, which are made of, e.g., TiN, W and Al alloy, respectively, so that the structure shown in FIG. 12 is completed.

In this embodiment, a sum of thicknesses of silicide layers 7a and 107a on doped polycrystalline silicon layer 6 depends on the position, and total thickness T_{A} of the portions in contact hole 11a is larger than total thickness T_{B} of the portions outside contact hole 11a. Thus, silicide layer 7a thus formed compensates silicide layer 107a for shaving caused during formation of contact hole 11a. Therefore, reduction in interconnection resistances of gate electrode layers 6 and 107a can be prevented, and reduction in drive performance of the transistor can be prevented.

A sum of the thicknesses of silicide layers 7b and 107b on heavily doped diffusion region 4b depends on the position, and total thickness T_{c} of the portions in contact hole 11 is larger than total thickness T_{D} of the portions outside contact hole 11b. Thus, silicide layer 7b compensates source/drain regions 4 for shaving caused during formation of contact hole 11b.

In the manufacturing method of this embodiment, both silicide layers 107a and 107b as well as both silicide layers 7a and 7b can be formed in the self-aligning manner. Therefore, especial steps such as a photolithography step for forming the respective silicide layers are not required, and the manufacturing steps can be simplified.

This embodiment has been described in connection with the structure wherein both silicide layers 107a and 7a are made of CoSi₂. However, these silicide layers may be made of different materials, respectively. Also, silicide layers 107b and 7b may be made of different materials, respectively. For example, if silicide layers 7a and 7b are made of CoSi₂, silicide layers 107a and 107b are made of TiSi₂ or WSi₂. If silicide layers 107a and 107b are made of CoSi₂, silicide layers 7a and 7b may be made of TiSi₂ or WSi₂.

Even if silicide layers 107a and 7a are made of the same material, these silicide layers 107a and 7a can be discriminated from each other. Likewise, silicide layers 107b and 7b can be discriminated from each other.

Embodiment 3

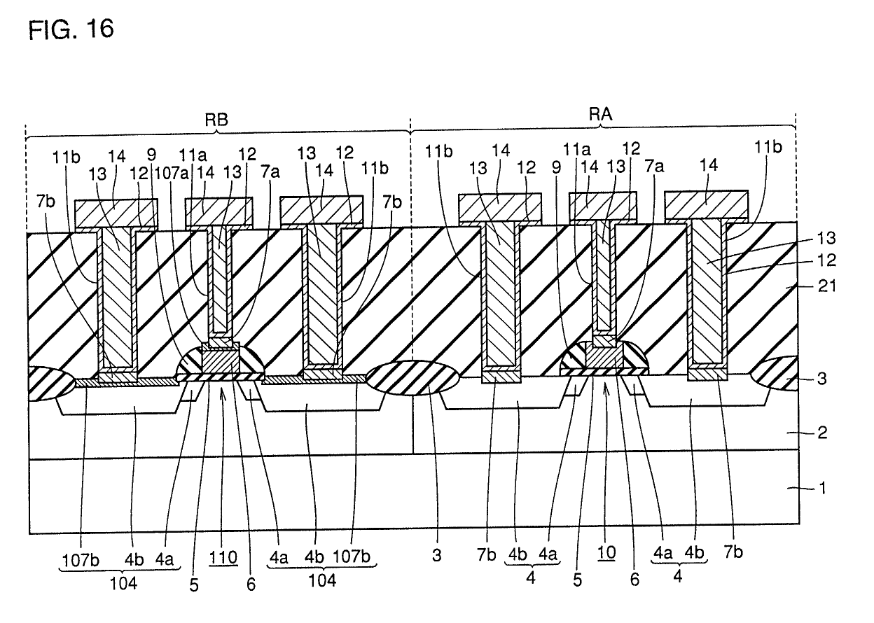

Referring to FIG. 16, a structure of this embodiment includes a first region RA where the semiconductor element of the embodiment 1 shown in FIG. 1 is formed, and a second region RB where the semiconductor element of the embodiment 2 shown in FIG. 12 is formed. Thus, two kinds of MOS transistors 10 and 110 are formed in a mixed fashion in this embodiment. First region RA is, e.g., a DRAM (Dynamic Random Access Memory) portion or a sensor portion, and second region RB is, e.g., a logic portion.

Structures other than the above are substantially the same as those of the embodiments 1 and 2. The substantially same members bear the same reference numbers, and will not be described.

A manufacturing method of this embodiment will now be described.

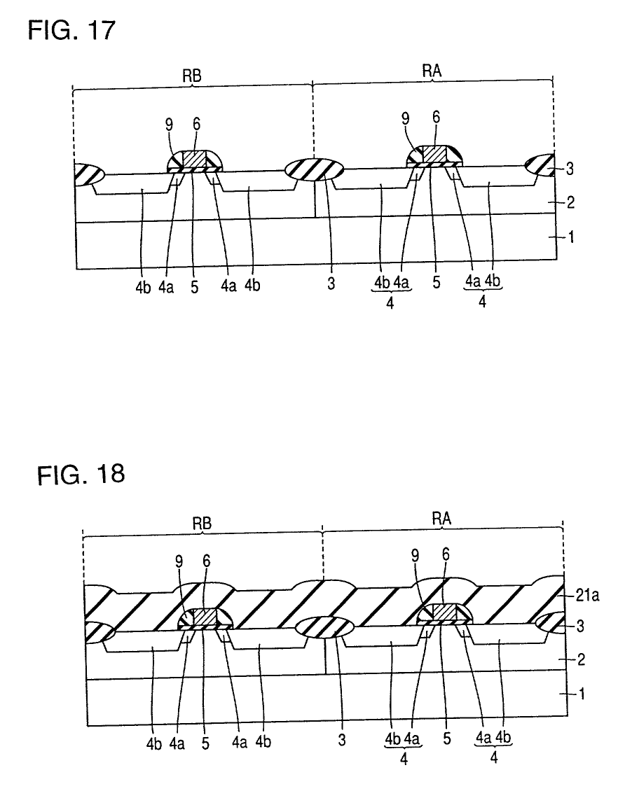

According to the manufacturing method of this embodiment, steps similar to those of the embodiment 1 shown in FIGS. 2 to 8 are executed. Thereby, a structure shown in FIG. 17 is formed.

Referring to FIG. 18, insulating layer 21a made of, e.g., an oxide film containing TEOS (Tetra Ethyl Ortho Silicate) and having a thickness of several 10 nm is then formed.

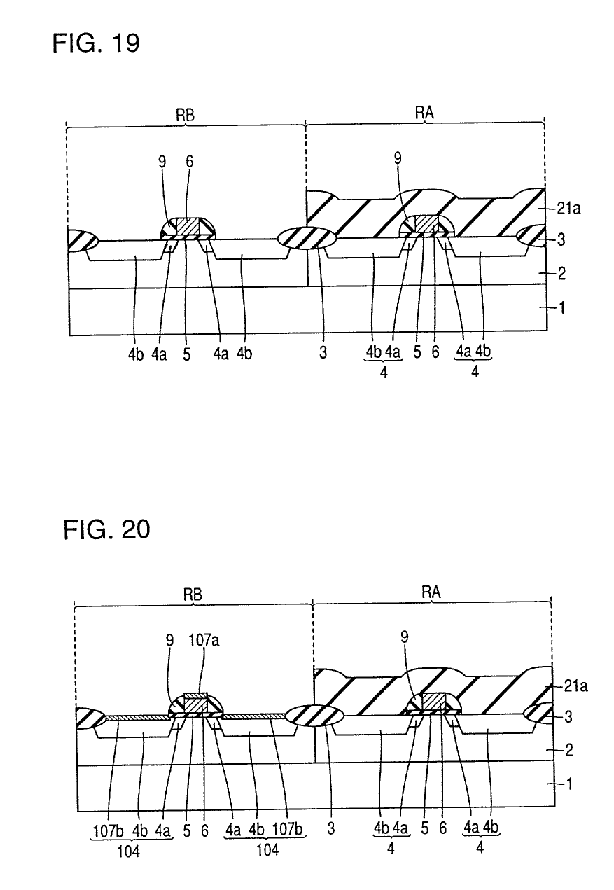

Referring to FIG. 19, the ordinary photolithography and etching technique (e.g., dry etching) are executed to remove the portion of insulating layer 21a forming second region RB.

Referring to FIG. 20, the structure is processed through the steps, which are already described in connection with the prior art with reference to FIGS. 30 to 32, so that silicide layers 107a and 107b made of, e.g., CoSi₂ are formed on doped polycrystalline silicon layer 6 and heavily doped diffusion region 4b, respectively.

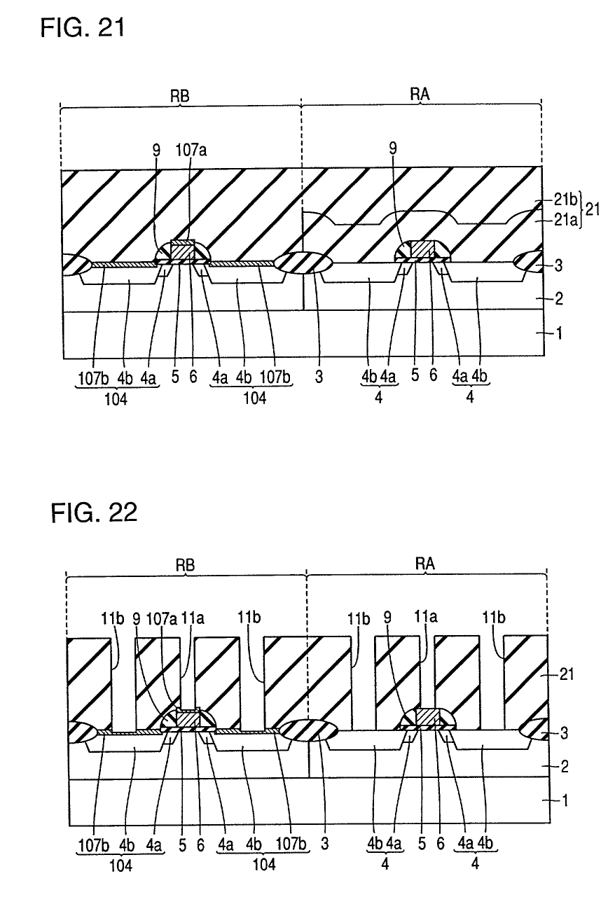

Referring to FIG. 21, insulating layer 21b made of USG, BPSG or the like is formed on the entire surface, and then flattening is effected on insulating layer 21b.

Referring to FIG. 22, the ordinary photolithography and etching technique (e.g., oxide film etching with plasma) are effected on insulating layer 21 to form contact hole 11a reaching the gate electrode layer and contact holes 11b reaching the source/drain regions. Thereafter, the metal layer made of, e.g., cobalt is formed on the entire surface, and first annealing is effected. Thereby, the CoSi layers are formed in the regions where the metal layer is in contact with the gate electrode layer and the source/drain regions, respectively.

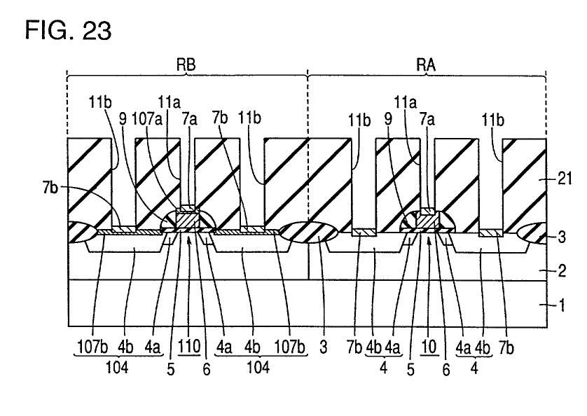

Thereafter, unreacted metal layer made of cobalt is removed, and then second annealing is performed. Thereby, the composition of CoSi layer changes so that silicide layers 7a and 7b made of CoSi₂ shown in FIG. 23 are formed. Thereafter, barrier metal layers 12, plug layers 13 and interconnection layers 14, which are made of, e.g., titanium nitride, tungsten and aluminum alloy, respectively, are formed so that the structure shown in FIG. 16 is completed.

In this embodiment, an effect similar to that of the embodiment 1 is achieved in first region RA, and an effect similar to that of the embodiment 2 is achieved in second region RB.

In the manufacturing method of this embodiment, a majority of steps can be commonly used for forming first and second regions RA and RB except for the steps of forming silicide layers 107a and 107b in second region RB. Therefore, two kinds of transistors can be manufactured through a small number of manufacturing steps.

Embodiment 4

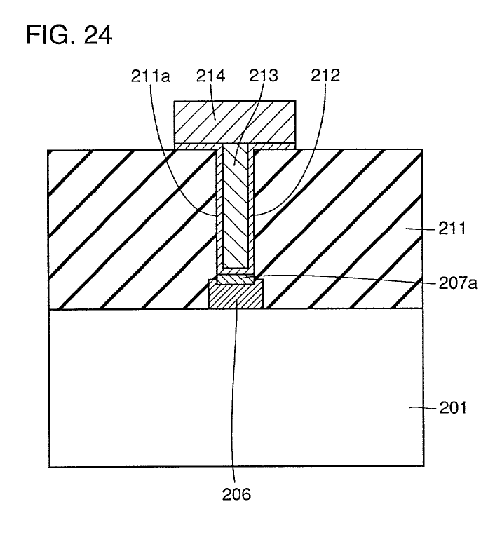

Referring to FIG. 24, a patterned conductive layer 206 made of, e.g., doped polycrystalline silicon is formed on a substrate or insulating layer 201. An insulating layer 211 made of, e.g., USG, BPSG or the like is formed over conductive layer 206. Insulating layer 211 is provided with a contact hole 211a reaching the surface of conductive layer 206. A silicide layer 207a which is in direct contact with conductive layer 206 is formed in contact hole 211a and is located only in the bottom portion thereof. Contact hole 211a is filled with a plug layer 213 made of W with a barrier metal layer 212 made of e.g., TiN therebetween. An interconnection layer 214, which is made of, e.g., Al alloy and is patterned into a predetermined configuration, is formed on insulating layer 211, and is in contact with plug layer 213 and barrier metal layer 212.

A manufacturing method of this embodiment will now be described.

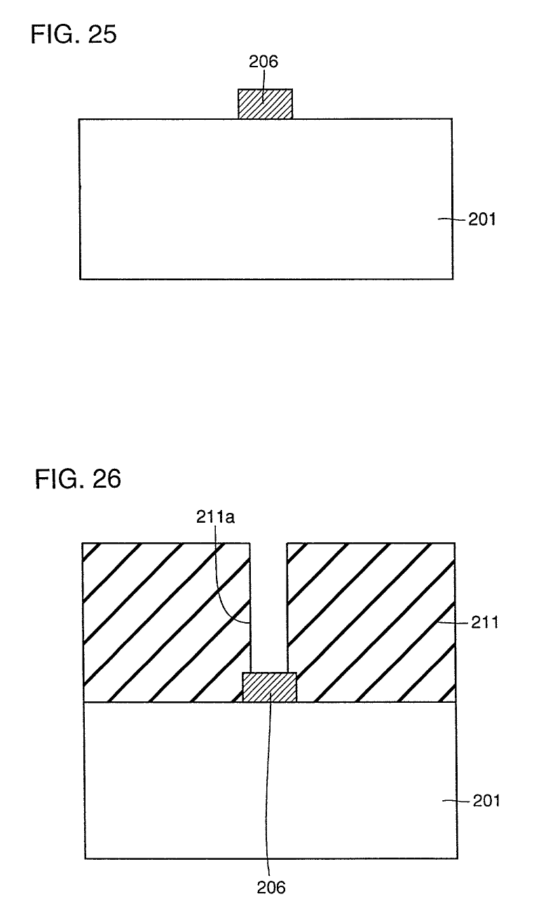

Referring first to FIG. 25, processing is performed to form patterned conductive layer 206 made of, e.g., doped polycrystalline silicon on silicon substrate or insulating layer 201. Conductive layer 206 will form, e.g., the gate electrode layer or the interconnection layer.

Referring to FIG. 26, insulating layer 211 made of USG, BPSG or the like is formed over conductive layer 206. Oxide film etching is effected on insulating layer 211 with plasma so that contact hole 211a reaching conductive layer 206 is formed.

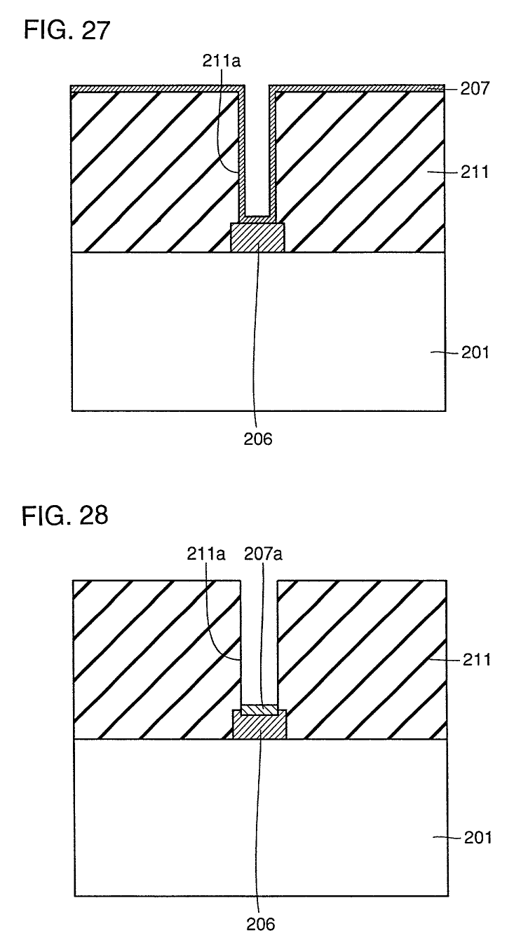

Referring to FIG. 27, metal layer 207 made of, e.g., Co is deposited on the whole surface by sputtering. Thereafter, first annealing is effected so that reaction between Si and Co occurs in the contact region between metal layer 207 and conductive layer 206, and thereby the CoSi layer is formed. Thereafter, the other portions, i.e., unreacted portions are removed by mixed acid.

Thereby, as shown in FIG. 28, CoSi layer 207a which is in direct contact with conductive layer 206 is formed in contact hole 211a and is located only in the bottom portion thereof Thereafter, second annealing is effected to change the composition of CoSi layer 207a so that silicide layer 207a made of CoSi₂ is formed.

Thereafter, barrier metal layer 212 made of, e.g., TiN, plug layer 213 made of, e.g., W and interconnection layer 214 made of, e.g., Al alloy are formed so that the structure shown in FIG. 24 is completed.

In the structure of this embodiment, silicide layer 207a which is in contact with conductive layer 206 is formed in contact hole 211a reaching conductive layer 206 and is located only in the bottom portion thereof Therefore, silicide layer 207a can compensate conductive layer 206 for shaving of its top surface caused by overetching during formation of contact hole 211a. Accordingly, increase in interconnection resistance of conductive layer 206 can be prevented.

Since silicide layer 207a is present between interconnection layer 214 and conductive layer 206, the contact resistance between interconnection layer 214 and conductive layer 206 can be small.

According to the manufacturing method of this embodiment, silicide layer 207a can be formed in the self-aligning manner as shown in FIGS. 27 and 28. Therefore, especial steps such as a photolithography step are not required for forming the silicide layer 207a, and the manufacturing steps can be simplified.

In the embodiments 1 to 4 described above, CoSi₂ has been described as an example of the silicide layer. However, the invention is not restricted to this, and may be applied to other metal silicide of, e.g., Ti (titanium) and W.

The embodiments 1 to 3 have been described in connection with the MOS transistors. However, the invention can be applied to MIS (Metal Insulator Semiconductor) transistors.

The embodiments 1 to 4 have been described in connection with the structure using doped polycrystalline silicon layers 6 and 206. According to the invention, however, an amorphous silicon layer doped with impurity may be used instead of the doped polycrystalline silicon layer, or other materials which contain silicon and can cause the siliciding reaction may be used.

The embodiments 1 to 3 have been described in connection with the nMOS transistors. However, the invention can likewise be applied to PMOS transistors.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device comprising:
a conductive layer patterned and including a silicon layer:
an insulating layer covering said conductive layer and having a first hole reaching said conductive layer;
a first silicide layer formed only within said first hole, located only in a bottom portion of said first hole and being in contact with said conductive layer; and
a first interconnection layer electrically connected to said first silicide layer through said first hole.

2. The semiconductor device according to claim 1, further comprising:
a semiconductor substrate having a main surface;
a conductive region including an impurity region formed at the main surface of said semiconductor substrate,
said insulating layer having a second hole reaching said conductive region;
a second silicide layer formed only in said second hole, located only in the bottom portion of said second hole and being in contact with said conductive region; and
a second interconnection layer electrically connected to said second silicide layer through said second hole.

3. The semiconductor device according to claim 1, wherein
said conductive layer has a third silicide layer in contact with the top surface of said silicon layer, and
a silicide layer for the silicon layer formed of said first and third silicide layers has a first portion located outside said first hole and a second portion located in said first hole and having a larger thickness than the first portion.

4. The semiconductor device according to claim 3, wherein
said conductive region has a fourth silicide layer in contact with the top surface of said impurity region, and
a silicide layer for the impurity region formed of said second and fourth silicide layers has a third portion located outside said second hole and a fourth portion located in said second hole and having a larger thickness than the third portion.

5. The semiconductor device according to claim 4, further comprising:
a first insulated gate type field-effect transistor having a gate electrode layer formed of said silicon layer and source/drain region formed of said impurity region; and
a second insulated gate type field-effect transistor having a gate electrode layer formed of said silicon layer and said third silicide layer, and source/drain region formed of said impurity region and said fourth silicide layer.

6. A method of manufacturing a semiconductor device comprising the steps of:
forming a conductive layer including a silicon layer by patterning;
forming an insulating layer covering said conductive layer and having a first hole reaching said conductive layer;
forming a first metal layer on said insulating layer and in said first hole;
forming only in said first hole a first silicide layer located only in the bottom portion of said first hole and being in contact with said conductive layer by changing a contact portion between said first metal layer and said conductive layer into silicide; and
forming a first interconnection layer electrically connected to said first silicide layer through said first hole.

7. The method of manufacturing the semiconductor device according to claim 6, further comprising the steps of:
forming a conductive region including an impurity region at a main surface of a semiconductor substrate;
forming in said insulating layer a second hole reaching said conductive region;
forming only in said second hole a second silicide layer located only in the bottom portion of said second hole and being in contact with said conductive region by changing said metal layer formed in said second hole into silicide; and
forming a second interconnection layer electrically connected to said second silicide layer through said second hole.

8. The method of manufacturing the semiconductor device according to claim 6, wherein
said conductive layer is formed to have a third silicide layer in contact with the top surface of said silicon layer, and
a silicide layer for the silicon layer formed of said first and third silicide layers has a first portion located outside said first hole and a second portion located in said first hole and having a larger thickness that the first portion.

9. The method of manufacturing the semiconductor device according to claim 8, wherein
said conductive region is formed to have a fourth silicide layer located at said main surface and being in contact with the top surface of said impurity region, and
a silicide layer for the impurity region formed of said second and fourth silicide layers has a third portion located outside said second hole and a fourth portion located in said second hole and having a larger thickness than the third portion.

10. The method of manufacturing the semiconductor device according to claim 9, wherein
the step of forming said third and fourth silicide layers further includes the steps of:
forming a second metal layer in contact with the top surfaces of said impurity region and said silicon layer; and
forming a third silicide layer located on the top surface of said silicon layer and a fourth silicide layer located on the top surface of said impurity region by changing a contact portion between said second metal layer and said impurity region and a contact portion between said second metal layer and said silicon layer into silicide, respectively.

11. The method of manufacturing the semiconductor device according to claim 10, wherein
a first insulated gate type field-effect transistor having a gate electrode layer formed of said silicon layer and source/drain region formed of said impurity region is formed, and
a second insulated gate type field-effect transistor having a gate electrode layer formed of said silicon layer and said third silicide layer, and source/drain region formed of said impurity region and said fourth silicide layer is formed.
